(19) United States
(12) Patent Application Publication
(10) Pub. No.: US 2026/0271219 A1
(43) Pub. Date: Sep. 10, 2026

(54) COOLING APPARATUS

(71) Applicant: CANON KABUSHIKI KAISHA, Tokyo (JP)

(72) Inventor: YOSHINOBU OKANO, Saitama (JP)

(21) Appl. No.: 19/550,762

(22) Filed: Feb. 26, 2026

(30) Foreign Application Priority Data
Mar. 10, 2025 (JP) 2025-037095

(51) Int. Cl. H05K 7/20; G03B 17/55

(52) U.S. Cl. CPC H05K 7/20145; G03B 17/55

(57) ABSTRACT

A cooling apparatus is configured to cool an image pickup apparatus and includes a fan unit configured to blow air, and an exhaust unit configured to blow the air from the fan unit against an exterior surface of the image pickup apparatus.

### BACKGROUND

### Field of the Technology

The present disclosure relates to a cooling apparatus.

### Description of the Related Art

Some conventional cooling apparatuses use a cooling fan to deliver air into the inside of an image pickup apparatus for cooling its inside. Japanese Patent Application Laid-Open No. 2023-127217 discloses a cooling apparatus that includes a cooling fan disposed in a tilted orientation so as to efficiently supply cooling air into the interior of an electronic apparatus.

However, the cooling apparatus disclosed in Japanese Patent Application Laid-Open No. 2023-127217 cannot suppress an increase in temperature of the exterior surface of the image pickup apparatus in harsh imaging environments, such as in high-temperature conditions or under the flaming sun.

### SUMMARY

A cooling apparatus according to one aspect of the present disclosure may be configured to cool an image pickup apparatus and may include a fan unit configured to blow air, and an exhaust unit configured to blow the air from the fan unit against an exterior surface of the image pickup apparatus.

Features of the present disclosure will become apparent from the following description of embodiments with reference to the attached drawings. The following description of embodiments is described by way of example.

### BRIEF DESCRIPTION OF THE DRAWINGS

FIGS. 1A and 1B are perspective views of the exterior appearance of an imaging system according to each embodiment.

FIGS. 2A and 2B are lower perspective views of an image pickup apparatus according to each embodiment.

FIG. 3 is an exploded perspective view of the image pickup apparatus according to each embodiment.

FIG. 4 is an exploded perspective view of a rear cover portion and a side cover portion of the image pickup apparatus according to each embodiment.

FIG. 5 is an upper perspective view of a cooling apparatus according to a first embodiment.

FIG. 6 is an exploded perspective view of a cooling apparatus according to the first embodiment.

FIG. 7 is a sectional view of an imaging system according to the first embodiment.

FIG. 8 is an upper perspective view of a cooling apparatus according to a second embodiment.

FIG. 9 is an exploded perspective view of the cooling apparatus according to the second embodiment.

FIG. 10 is a sectional view of an imaging system according to the second embodiment.

FIG. 11 is an upper perspective view of a cooling apparatus according to a third embodiment.

FIG. 12 is an exploded perspective view of a cooling apparatus according to the third embodiment.

FIG. 13 is a sectional view of an imaging system according to the third embodiment.

### DESCRIPTION OF THE EMBODIMENTS

Referring now to the accompanying drawings, a detailed description will be given of embodiments according to the present disclosure.

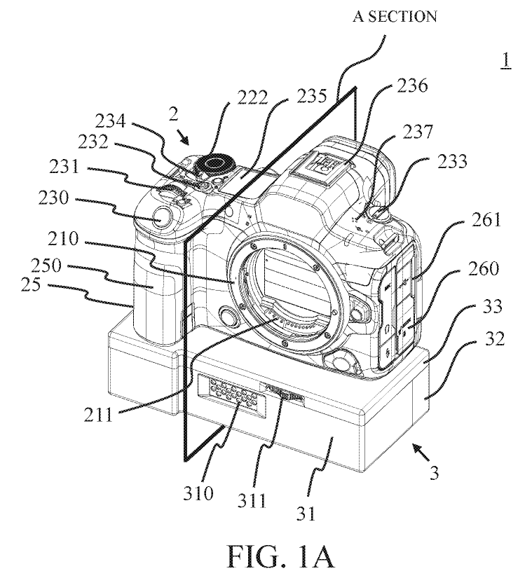

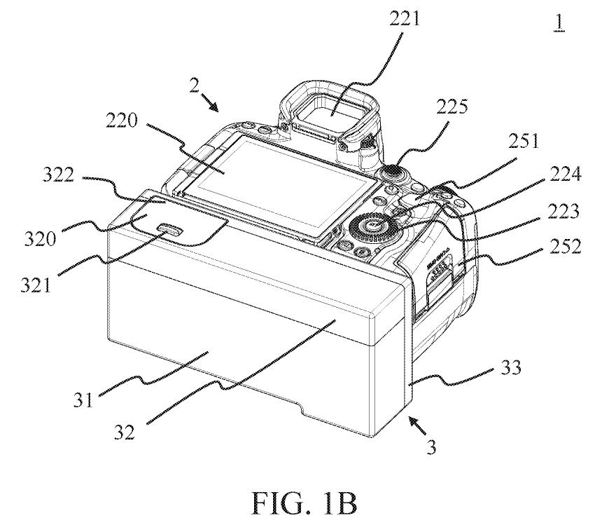

Referring now to FIGS. 1A and 1B, a description will be given of the structure of an imaging system (camera system) 1 according to each embodiment. FIGS. 1A and 1B are perspective views of the exterior appearance of the imaging system 1. FIG. 1A illustrates a front perspective view of the imaging system 1, and FIG. 1B illustrates a rear perspective view of the imaging system 1. In each embodiment, the imaging system 1 includes an image pickup apparatus (camera body) 2, a cooling apparatus 3, and an unillustrated lens apparatus (interchangeable lens). The structure of the image pickup apparatus 2 illustrated in FIGS. 1A and 1B is merely an example of the image pickup apparatus according to each embodiment. In each embodiment, the image pickup apparatus 2 is a mirrorless digital camera, but it may also be a digital video camera or an image pickup apparatus in which the image pickup apparatus 2 and the lens apparatus are integrated.

The image pickup apparatus 2 includes a mount 210 to which the lens apparatus can be detachably attached. Communication terminals 211, through which the image pickup apparatus 2 communicates with the lens apparatus, are arranged inside the mount 210. In the following description, unless otherwise specified, the side of the image pickup apparatus 2 on which the mount 210 for attaching the lens apparatus is located will be referred to as the front side, and the opposite side will be referred to as the rear side. A direction along the optical axis of the lens apparatus will be referred to as an optical axis direction. When viewing the image pickup apparatus 2 from the rear side, the left side will be referred to as a left side surface, the right side as a right side surface, the upper side as an upper surface, and the lower side as a lower surface. A variety of operation members are illustrated in FIGS. 1A and 1B, but those less relevant to the embodiments are not described.

Provided on the upper surface of the image pickup apparatus 2 are a shutter button 230 for issuing an imaging instruction, a main electronic dial 231 for changing a variety of setting values, and a moving image capturing button 232 for starting and stopping capturing (recording) a moving image. Provided on the upper surface of the image pickup apparatus 2 are a still/moving image switch 233 for switching between a still image capturing mode and a moving image capturing mode, a power switch 234 for turning on and off the power of the image pickup apparatus 2, and an upper display unit 235 for indicating a variety of setting values of the image pickup apparatus 2. In addition, provided on the upper surface of the image pickup apparatus 2 are an accessory shoe 236 for attaching and detaching external devices such as a video microphone, and an audio input unit 237 for acquiring audio input to the image pickup apparatus 2 during imaging.

Provided on the left side surface of the image pickup apparatus 2 are a connector (not illustrated) for connecting an external device such as a video microphone, a connector cover 260 for protecting the connector, and an exhaust port 261. The exhaust port 261 is an air outlet for exhausting air inside a camera duct 27 (described later) to the outside.

On the right side surface of the image pickup apparatus 2, a grip portion 25 for the user to hold the image pickup apparatus 2 is provided. The grip portion 25 has a shape that allows the user to easily hold it with the right hand from the front to the rear side, and includes a front rubber 250 on the front side and a rear rubber 251 on the rear side to prevent the hand from slipping.

A rear display unit 220 for displaying captured images and various information is provided at the central portion of the rear surface of the image pickup apparatus 2. A viewfinder 221 configured as an electronic viewfinder is provided on the upper surface of the image pickup apparatus 2.

On the right side surface of the image pickup apparatus 2, a sub electronic dial 222 and a rear electronic dial 223 for changing a variety of setting values similarly to the main electronic dial 231, a setting button 224 for confirming a selection, and a variety of operation members including a multi-controller 225 etc. are provided. The multi-controller 225 enables not only pressing the key top but also tilting the key top in a variety of directions, and is mainly used for moving a selection frame or for navigating and selecting items in various setting menus. A card slot cover 252 is also provided on the right side surface, disposed at the grip area of the grip portion 25.

Next, the structure of the cooling apparatus 3 will be described. An intake port 310 is provided at the center of the front side of the cooling apparatus 3. The intake port 310 is an inlet for drawing outside air into the interior of the cooling apparatus 3. A dial 311, which is an operation member for fixing the image pickup apparatus 2 and the cooling apparatus 3 together, is provided at the center of the upper surface of the cooling apparatus 3. A battery lid (battery cover) 320 is provided on the rear side of the cooling apparatus 3, and a battery cover knob 321 is provided at the center of the battery lid 320. The battery lid 320 can be opened and closed by pulling up and rotating the battery cover knob 321, and the battery lid 320 opens by the biasing force of a spring inside the battery cover, with a battery cover shaft portion 322 serving as a rotational axis.

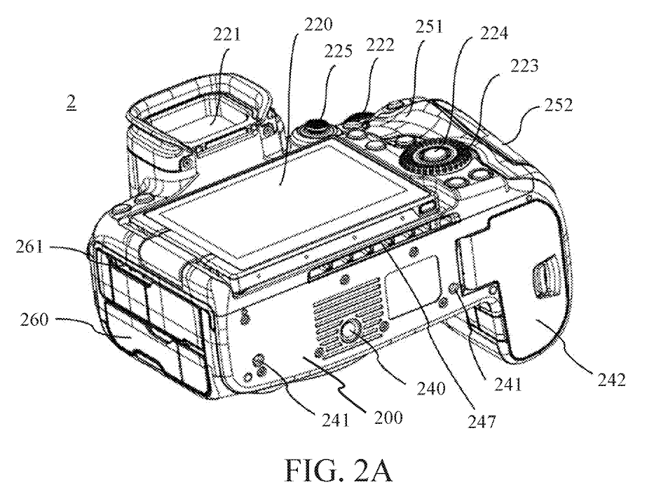

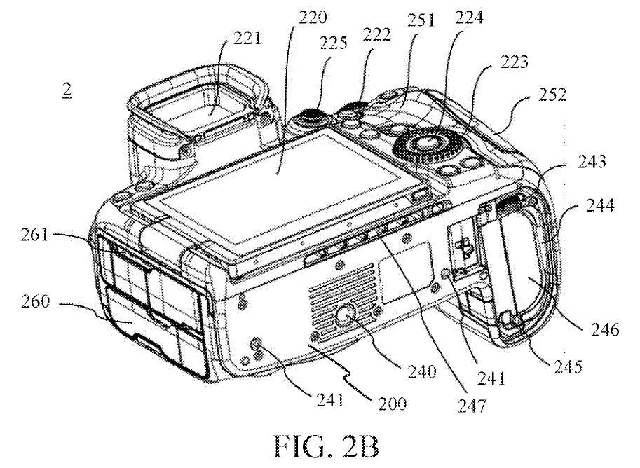

Next, with reference to FIGS. 2A and 2B, the structure of the lower surface of the image pickup apparatus 2 will be described. FIGS. 2A and 2B are lower perspective views of the image pickup apparatus 2. FIG. 2A illustrates a state in which a camera battery cover 242 is attached, and FIG. 2B illustrates a state in which the camera battery cover 242 is removed.

On the lower surface of the image pickup apparatus 2, a bottom cover portion 200, a camera female threaded member (tripod screw) 240, a positioning hole 241, the camera battery cover 242, a receptacle connector 243, a camera battery chamber 244, a camera battery lock lever 245, and an air vent 247 are provided.

The bottom cover portion 200 is an exterior member forming the lower surface of the image pickup apparatus 2 (i.e., the exterior surface (bottom surface) of the image pickup apparatus 2). The camera female threaded member 240 is used to fix the image pickup apparatus 2 to a tripod or the like when using the camera alone. In the present embodiment, the camera female threaded member 240 is used to fix the image pickup apparatus 2 and the cooling apparatus 3 together. The positioning hole 241 is disposed on both the left and right sides of the camera female threaded member 240, and engaged with a positioning pin 331 of the cooling apparatus 3 (described later) to align the relative positions of the image pickup apparatus 2 and the cooling apparatus 3.

The camera battery cover 242 is attached when the image pickup apparatus 2 is used alone, but is removed when the cooling apparatus 3 is attached. When the camera battery cover 242 is removed, the receptacle connector 243, the camera battery chamber 244, the battery 246, and the camera battery lock lever 245 are exposed. The receptacle connector 243 corresponds to various accessories including the cooling apparatus 3, which can be attached to and detached from the image pickup apparatus 2, and performs electrical signal exchange with these accessories. The camera battery chamber 244 houses the battery 246, and the camera battery lock lever 245 prevents the battery 246 from falling out by holding it. Although the cooling apparatus 3 is attachable to and detachable from the image pickup apparatus 2 in the present embodiment, the cooling apparatus 3 may be integrated with the image pickup apparatus 2.

The air vent 247 is an inlet for drawing air delivered from the cooling apparatus 3 into a camera duct 27 described later.

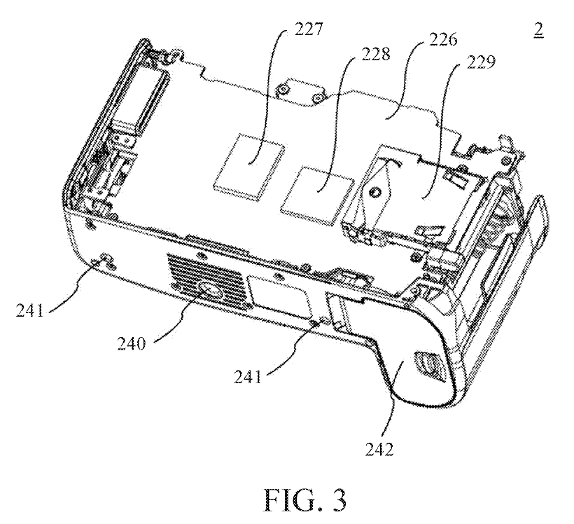

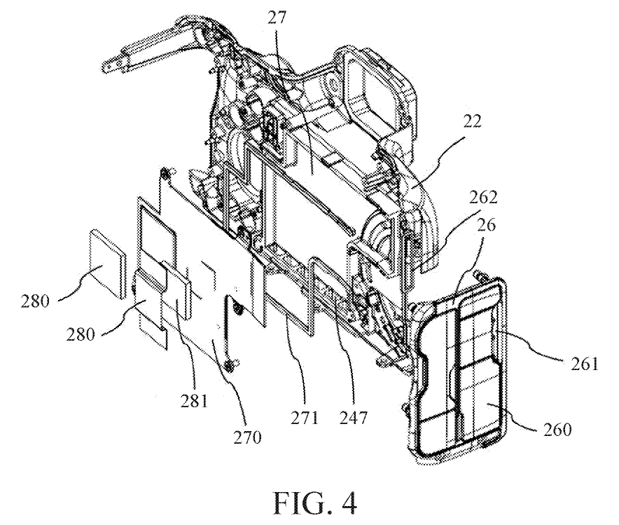

Next, with reference to FIGS. 3 and 4, the internal structure of the image pickup apparatus 2 will be described. FIG. 3 is an exploded perspective view illustrating a state in which part of the exterior members of the image pickup apparatus 2 is removed. FIG. 4 is an exploded perspective view of a rear cover portion and a side cover portion of the image pickup apparatus 2.

As illustrated in FIG. 3, a main substrate 226 is provided inside the image pickup apparatus 2 on the rear side. ICs 227 and 228 that perform image processing and the like, a card slot 229 that houses a recording card, power circuit components (not illustrated) for supplying power to various units, and various connectors (not illustrated) are mounted on the main substrate 226. For simplification, some mounted components and harnesses on the board are omitted in FIG. 3. The ICs 227 and 228 are main heat-source components on the main substrate 226, and their heat generation increases because they consume a large amount of power to perform image processing during high-resolution or high-frame-rate movie imaging.

As illustrated in FIG. 4, a camera duct 27 is provided inside the image pickup apparatus 2 on the rear side. The camera duct 27 includes a rear cover 22 having the air vent 247 in the central part of the lower surface, a side cover 26 having the exhaust port 261, a heat-dissipating metal plate 270 made of aluminum or other material with good thermal conductivity, a rear seal member 271 such as Poron or double-sided tape, and an exhaust port seal member 262.

As described above, the air vent 247 is an inlet for drawing air delivered from the cooling apparatus 3 into the camera duct 27. The exhaust port 261 is an outlet for exhausting to the outside the air drawn into the camera duct 27 from the air vent 247.

The camera duct 27 is formed by fixing the heat-dissipating metal plate 270 to the rear cover 22 via the rear seal member 271, and fixing the side cover 26 to the rear cover 22 via the exhaust port seal member 262, thereby forming an air passage (airflow path) communicating from the air vent 247 to the exhaust port 261. A heat transfer member 280, such as a thermal interface sheet, is attached to the heat-dissipating metal plate 270. In the present embodiment, the heat transfer member 280 is attached using a buffer member 281 or double-sided tape so as to contact the ICs 227 and 228, which are the main heat sources, and transfers heat generated by the ICs 227 and 228 to the heat-dissipating metal plate 270. The camera duct 27 including the heat-dissipating metal plate 270 functions as a heat exchange unit serving as an air passage for air introduced from the air vent 247.

The embodiments of the present disclosure will be described in detail below.

### First Embodiment

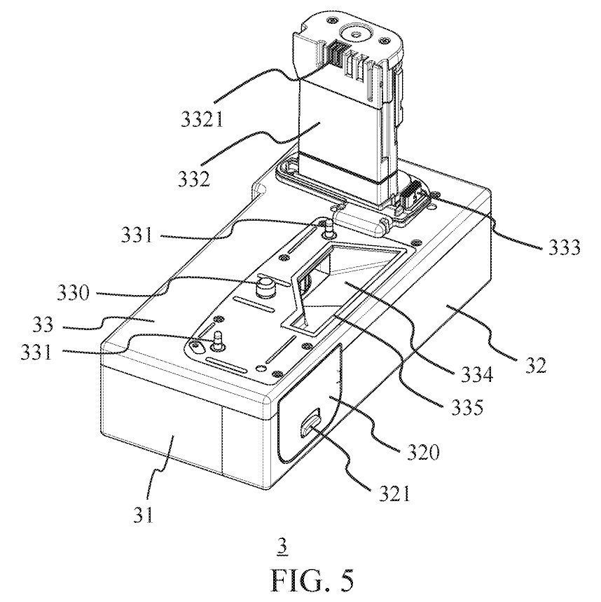

First, the structure of the cooling apparatus 3 in the first embodiment will be described. With reference to FIG. 5, the external structure of the cooling apparatus 3 will be described. FIG. 5 is an upper perspective view of the cooling apparatus 3.

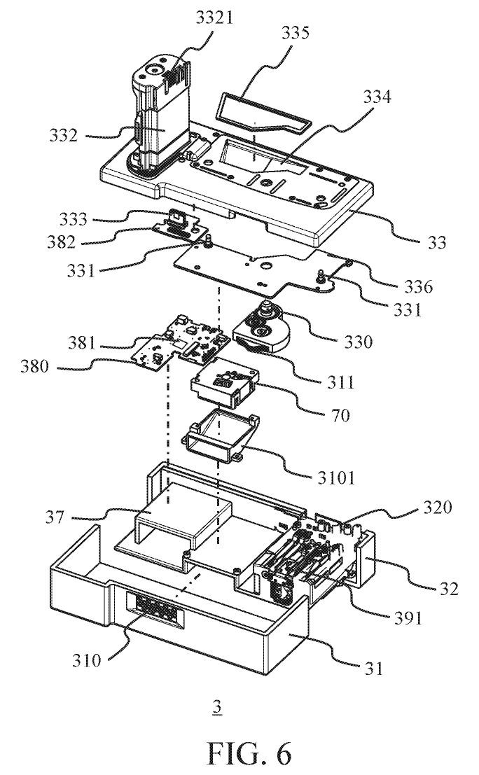

On the upper surface of the cooling apparatus 3, a male threaded member (attachment member) 330, a positioning pin 331, a tower portion 332, a plug connector 333, and a blower outlet (exhaust unit) 334 are provided. The male threaded member 330 rotates in association with the operation of a dial 311 illustrated in FIG. 6 and screws into the camera female threaded member 240 of the camera, thereby attaching (coupling, fixing) the cooling apparatus 3 to the image pickup apparatus 2. The positioning pin 331 is engaged with the positioning hole 241 of the image pickup apparatus 2 to align the relative positions of the image pickup apparatus 2 and the cooling apparatus 3.

The tower portion 332 includes a tower terminal 3321 at its tip. When attaching the cooling apparatus 3 to the image pickup apparatus 2, the tower portion 332 is inserted into the camera battery chamber 244 while the camera battery cover 242 is removed. At this time, the tower terminal 3321 connects to battery contacts provided in the camera battery chamber 244, and supplies power from a battery stored in the cooling apparatus 3 to the image pickup apparatus 2. The plug connector 333 connects to the receptacle connector 243 when attaching the cooling apparatus 3 to the image pickup apparatus 2 while the camera battery cover 242 is removed. At this time, the image pickup apparatus 2 and the cooling apparatus 3 are electrically connected, and exchange various electrical signals.

The air outlet 334 is provided on the upper surface of the cooling apparatus 3 and is connected to the air vent 247 provided on the lower surface of the image pickup apparatus 2. The air outlet 334 serves as an outlet that sends air, discharged from the cooling fan 70 described later, to the air vent 247.

Next, with reference to FIG. 6, the internal structure of the cooling apparatus 3 will be described. FIG. 6 is an exploded perspective view of the cooling apparatus 3. For simplification, some mounted components on the substrate, harnesses, fastening members, and the like are omitted in FIG. 6.

The cooling apparatus 3 includes a front cover portion 31 on the front side, a rear cover portion 32 on the rear side, an upper cover portion 33 on the upper side, and a body portion 37 that is an internal structural body. The front cover portion 31 includes an intake port 310. The rear cover portion 32 includes a battery lid 320. The upper cover portion 33 includes a tower portion 332 having a tower terminal 3321, a plug-connector substrate 382 having plug connectors 333, an air outlet 334, and an air-outlet sealing member 335. The body portion 37 includes a cooling fan 70, an intake port-side duct 3101, a dial 311, a male threaded member 330, a top plate 336, a positioning pin 331 fixed to the upper plate, an accessory substrate 380, and a battery armature 391.

The cooling fan 70 is a fan unit that takes in air passing through the intake port 310 and the intake port-side duct 3101 and discharges (blows) the air toward the air outlet 334. Placing the cooling fan 70 at the center in the left-right direction of the cooling apparatus 3 enables the left-right position to be aligned with the air vent 247 provided at the center on the lower surface side of the image pickup apparatus 2. Thereby, the airflow path from the cooling fan 70 to the air outlet 334 can be formed without bending it in the left-right direction, thereby suppressing a decrease in airflow due to flow-path losses.

Around the air outlet 334, an air-outlet sealing member 335 is provided to prevent air leakage between the air outlet 334 and the air vent 247 of the image pickup apparatus 2. Thereby, when the cooling apparatus 3 is attached to the image pickup apparatus 2, an air-flow path communicating from the intake port 310 of the cooling apparatus 3 to the exhaust port 261 of the image pickup apparatus 2 is formed.

The accessory substrate 380 is mounted with a control unit 381 such as a CPU for communication with the image pickup apparatus 2 and for controlling the cooling fan 70, as well as a power-supply circuit unit and other components that supply power to the respective parts. The accessory substrate 380 is electrically connected via harnesses and connectors to the tower terminal 3321 provided at the tip of the tower portion 332, the plug connector 333 on the plug-connector substrate 382, and the battery armature 391 provided on the upper side of the battery chamber 326.

The control unit 381 is connected to the plug connector 333 via the accessory substrate 380 and the plug-connector substrate 382. The cooling apparatus 3 attached to the image pickup apparatus 2 is connected to the image pickup apparatus 2 via the receptacle connector 243. Thereby, the image pickup apparatus 2 can perform various communications with the cooling apparatus 3, such as acquiring the rotational state of the cooling fan 70. In this embodiment, the control unit 381 is disposed on the accessory substrate 380 of the cooling apparatus 3, but it may alternatively be disposed on another substrate such as the main substrate 226 of the image pickup apparatus 2.

The battery armature 391 is connected to the battery 246 inserted into the body portion 37. The battery armature 391 is connected to the tower terminal 3321 via the accessory substrate 380. The cooling apparatus 3 attached to the image pickup apparatus 2 is connected to the image pickup apparatus 2 via the battery armature provided in the camera battery chamber 244. Thereby, the image pickup apparatus 2 can be driven by receiving power supplied from the battery 246 inserted in the battery chamber 326.

The front cover portion 31 is fixed to the body portion 37, and the upper cover portion 33 is fixed to the body portion 37. Thereby, an air-flow path communicating from the intake port 310 to the air outlet 334 is formed, and in this embodiment, the cooling fan 70 is disposed within the flow path.

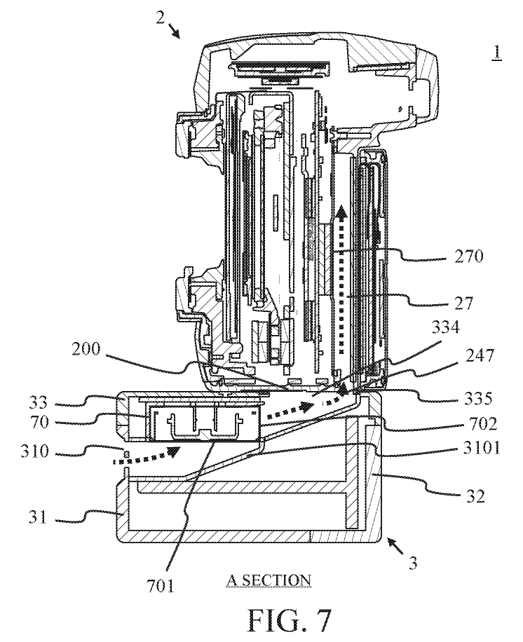

Next, with reference to FIG. 7, the internal structure of the imaging system 1 according to this embodiment will be described. FIG. 7 is a sectional view taken along a line A-A in FIG. 1A orthogonal to the left-right direction of the imaging system 1. When the cooling fan 70 is rotated (driven), outside air is taken in from the intake port 310 through the intake port-side duct 3101 into the cooling-fan intake port 701. Then, the cooling fan 70 discharges (blows) the air taken in from outside through the cooling-fan exhaust port 702 by rotation of its blades.

The air outlet 334 discharges the air expelled from the cooling-fan exhaust port 702. The camera duct 27 takes in the air discharged from the air outlet 334 through the air vent 247 of the image pickup apparatus 2 and discharges it from the exhaust port 261 of the image pickup apparatus 2.

As illustrated in FIG. 7, in this embodiment, the opening of the air outlet 334 when viewed from above the cooling apparatus 3 is widely opened in the region (range) between the cooling-fan exhaust port 702 and the air vent 247 in the optical axis direction. With this structure, the air outlet 334 discharges the air expelled from the cooling-fan exhaust port 702 by guiding it along the inner wall portion of the cooling apparatus 3 and the bottom cover portion 200 of the image pickup apparatus 2. That is, the air outlet 334 blows the air from the cooling fan 70 against the bottom cover portion 200 (exterior surface) of the image pickup apparatus 2. More specifically, the air outlet 334 blows the air from the cooling fan 70 against the exterior surface of the image pickup apparatus 2, and then introduces it into the interior of the image pickup apparatus 2.

At this time, the bottom cover portion 200 of the image pickup apparatus 2 is cooled because it contacts the air discharged from the cooling-fan exhaust port 702 (the bottom cover portion 200 has a surface in contact with air). The heat-dissipating metal plate 270 is cooled by contacting the air passing through the camera duct 27, thereby dissipating heat from the ICs 227 and 228 via the heat transfer member 280.

Thereby, both the interior and the exterior components (exterior surface) of the image pickup apparatus 2 can be efficiently cooled simultaneously using a single cooling fan 70. Thus, even in harsh imaging environments such as high-temperature environments or under the flaming sun, the driving time of the image pickup apparatus 2 can be extended compared with the image pickup apparatus 2 alone, without reducing the imageable time.

In this embodiment, the cooling fan 70 is a centrifugal fan (centrifugal fan unit) that takes in air from the cooling-fan intake port 701 provided in the blade-rotation axis direction and discharges air from the cooling-fan exhaust port 702 provided in the rotation diameter direction of the blades. However, this embodiment is not limited to this example, and the cooling fan 70 may also be an axial (flow) fan (axial fan unit) that performs air intake and exhaust in the rotation axis direction of the blades. In this embodiment, the cooling fan 70 is disposed such that the cooling-fan exhaust port 702, which discharges the taken-in air, is aligned with the optical-axis direction, but it may instead be disposed in the vertical direction perpendicular to the optical-axis direction or in an oblique direction.

### Second Embodiment

Next, the structure of the cooling apparatus 3 (3a) according to the second embodiment of the present disclosure will be described. A description common to that in the first embodiment will be omitted.

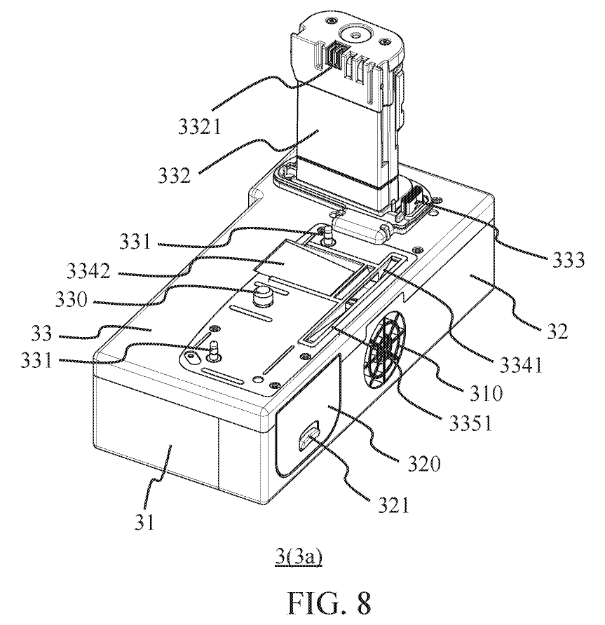

First, with reference to FIG. 8, the external structure of the cooling apparatus 3 (3a) will be described. FIG. 8 is an upper perspective view of the cooling apparatus 3 (3a). Provided on the upper surface of the cooling apparatus 3, unlike in the first embodiment, is an exhaust unit having two air outlets (exhaust ports), a first air outlet (first exhaust port) 3341 and a second air outlet (second exhaust port) 3342. The cooling fan 70 branches air toward the first air outlet 3341 and the second air outlet 3342 and blows the air toward the lower surface of the image pickup apparatus 2. The first air outlet 3341 is an air outlet for introducing air into the interior of the image pickup apparatus 2. The second air outlet 3342 is an air outlet for blowing air against the exterior surface of the image pickup apparatus 2. Details of this will be described later.

An intake port 310 is provided on the rear side of the cooling apparatus 3. In the first embodiment, the intake port 310 is provided in the front cover portion 31 of the cooling apparatus 3, but in this embodiment, the intake port 310 is provided in the rear cover portion 32. In addition, in this embodiment, the cooling-fan intake port 701 is provided in the rear cover portion 32, but as in the first embodiment, it may alternatively be provided in the front cover portion 31.

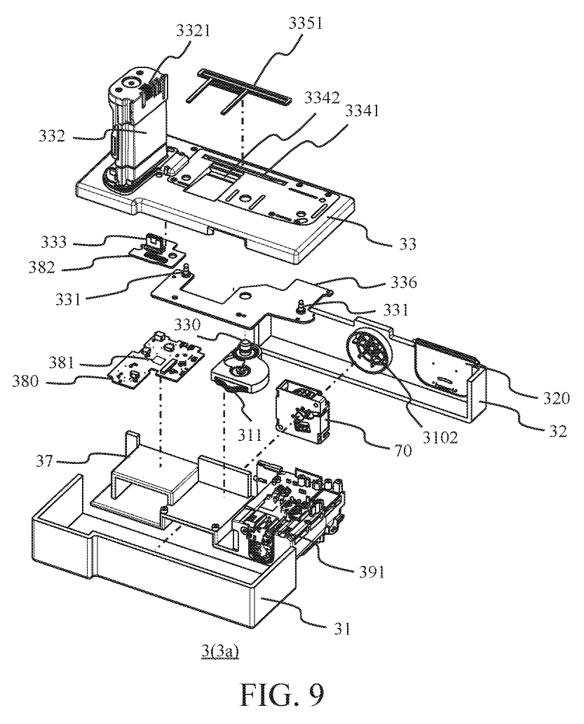

Next, with reference to FIG. 9, the internal structure of the cooling apparatus 3 (3a) will be described. FIG. 9 is an exploded perspective view of the cooling apparatus 3 (3a). For simplification, some mounted components on the substrate, harnesses, fastening members, and the like are omitted in FIG. 9.

The rear cover portion 32 includes the battery lid 320 and an intake port-side duct 3102. The upper cover portion 33 includes the first air outlet 3341, the second air outlet 3342, and an air-outlet sealing member 3351.

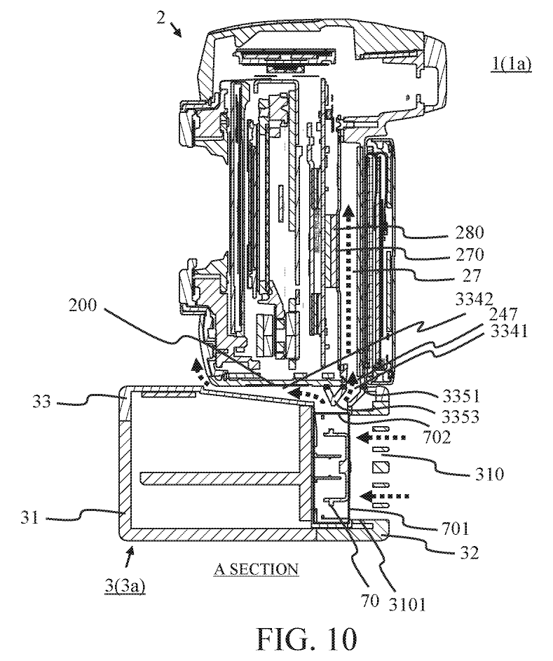

The cooling fan 70 takes in air passing through the intake port 310 and the intake port-side duct 3102 and discharges the air divided into the first air outlet 3341 and the second air outlet 3342 by a partition 3353 (see FIG. 10) formed by the upper cover portion 33. The partition 3353 is a branching portion that divides the air from the cooling fan 70 into the air directed toward the first air outlet 3341 and the air directed toward the second air outlet 3342.

Placing the cooling fan 70 at the center in the left-right direction of the cooling apparatus 3 (3a) enables the left-right position to be aligned with the air vent 247 provided at the center of the lower surface side of the image pickup apparatus 2. Thereby, the airflow path from the cooling fan 70 to the first air outlet 3341 can be formed without bending it in the left-right direction, thereby suppressing a decrease in airflow due to flow-path losses.

An air-outlet sealing member 3351 is provided around the first air outlet 3341 and the second air outlet 3342. Around the first air outlet 3341, the air-outlet sealing member 3351 is formed over the entire circumference in order to prevent air leakage between the first air outlet 3341 and the air vent 247 of the image pickup apparatus 2. On the other hand, the air-outlet sealing member 3351 around the second air outlet 3342 is open on the front side of the image pickup apparatus 2. The opening of the air-outlet sealing member 3351 exhausts air discharged from the second air outlet 3342.

Next, with reference to FIG. 10, the internal structure of the imaging system 1 (1a) according to this embodiment will be described. FIG. 10 is a sectional view taken along a line A-A in FIG. 1A in a direction orthogonal to the left-right direction of the imaging system 1 (1a).

When the cooling fan 70 rotates, outside air is taken in from the intake port 310, through the intake-port-side duct 3101, and into the cooling-fan intake port 701 of the cooling fan 70. The cooling fan 70 then discharges the taken-in air from the cooling-fan exhaust port 702 by the rotation of its blades.

A partition 3353 formed by the upper cover portion 33 branches the air discharged from the cooling-fan exhaust port 702 into air directed toward the first air outlet 3341 and air directed toward the second air outlet 3342, and discharges the air. The camera duct 27 takes in the air discharged from the first air outlet 3341 through the air vent 247 of the image pickup apparatus 2 and discharges the air from the exhaust port 261 of the image pickup apparatus 2. The second air outlet 3342 is opened so that its front side is larger than the bottom cover portion 200 of the image pickup apparatus 2. That is, the first air outlet 3341 is configured so that the entire opening is covered by the image pickup apparatus 2, whereas the second air outlet 3342 is configured so that a part of the opening is exposed from the image pickup apparatus 2.

With this structure, the second air outlet 3342 discharges the air discharged from the second air outlet 3342 after allowing the air to travel along the inner wall of the cooling apparatus 3 and the bottom cover portion 200 of the image pickup apparatus 2, and then discharging the air from the front-side opening formed by the image pickup apparatus 2 and the cooling apparatus 3 (3a). That is, the front-side opening of the air-outlet sealing member 3351 serves as an air discharge port.

At this time, the bottom cover portion 200 of the image pickup apparatus 2 is cooled by coming into contact with the air discharged from the cooling-fan exhaust port 702 (the bottom cover portion 200 has a surface that comes into contact with the air). The heat-dissipating metal plate 270 is cooled by contact with the air passing through the camera duct 27, and dissipates heat from the ICs 227 and 228 via the heat transfer member 280.

Thereby, both the interior and the exterior member (external surface) of the image pickup apparatus 2 can be cooled efficiently at the same time by a single cooling fan 70. Thus, even in harsh imaging environments such as high-temperature environments or under the flaming sun, the driving time of the image pickup apparatus 2 can be extended without reducing the available imaging time, compared with the image pickup apparatus 2 alone.

In this embodiment, the cooling fan 70 is a centrifugal fan that takes in air from the cooling-fan intake port 701 provided in the rotation axis direction of the blades and discharges the air from the cooling-fan exhaust port 702 provided in the rotation diameter direction of the blades. However, the present embodiment is not limited to this example. The cooling fan 70 may also be an axial fan that performs intake and exhaust along the rotation axis direction of the blades. Moreover, in this embodiment, the cooling fan 70 is disposed such that the cooling-fan exhaust port 702 is aligned with the optical axis direction to discharge the taken-in air along the optical axis direction. However, the cooling fan 70 may instead be disposed in a vertical direction (perpendicular direction) perpendicular to the optical axis direction or in an oblique direction.

In this embodiment, the cooling apparatus 3 (3a) includes one cooling fan 70 and two air outlets, that is, the first air outlet 3341 and the second air outlet 3342, as the exhaust unit. However, the present embodiment is not limited to this example. It is also applicable to a cooling apparatus having a plurality of cooling fans and a plurality of air outlets, in which the number of the plurality of cooling fans is smaller than the number of the plurality of air outlets.

### Third Embodiment

Next, the structure of a cooling apparatus 3 (3b) according to a third embodiment of this disclosure will be described. A description common to that of each of the first or second embodiment will be omitted.

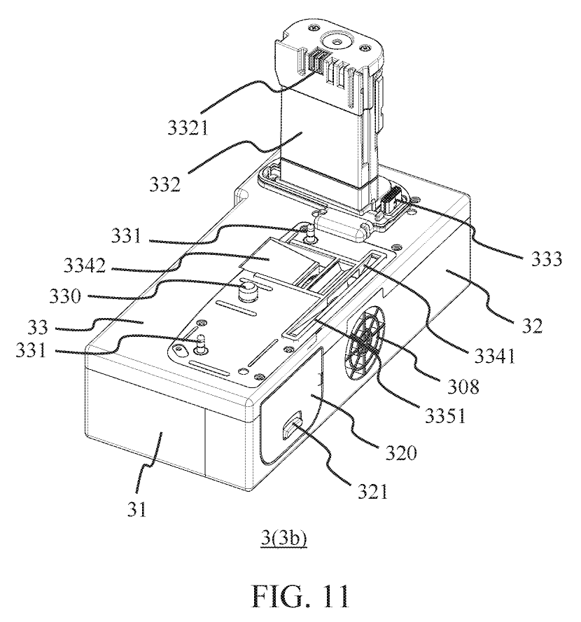

First, with reference to FIG. 11, the external structure of the cooling apparatus 3 (3b) will be described. FIG. 11 is an upper perspective view of the cooling apparatus 3 (3b). On the upper surface side of the cooling apparatus 3 (3b), the first air outlet (first exhaust port) 3341 and the second air outlet (second exhaust port) 3342 are provided. Details of the first air outlet 3341 and the second air outlet 3342 will be described later.

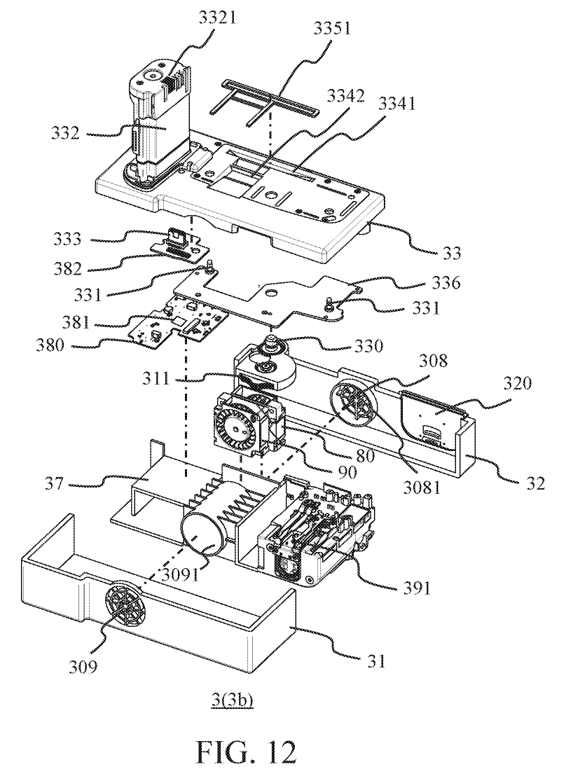

Next, with reference to FIG. 12, the internal structure of the cooling apparatus 3 (3b) will be described. FIG. 12 is an exploded perspective view of the cooling apparatus 3 (3b). For simplification, some components mounted on the substrate, harnesses, and fastening members are omitted.

The cooling apparatus 3 (3b) includes a front cover portion 31 on the front side, a rear cover portion 32 on the rear side, an upper cover portion 33 on the upper side, and a body portion 37 as an internal structure. The rear cover portion 32 includes a battery lid 320, a first intake port 308, and a first intake-port-side duct 3081. The upper cover portion 33 includes the first air outlet 3341, the second air outlet 3342, and an air-outlet sealing member 3351. The body portion 37 includes a first cooling fan 80, a second cooling fan 90, a dial 311, a male threaded member 330, a top plate 336, a positioning pin 331 fixed to the top plate, an accessory substrate 380, a battery armature 391, and a second intake-port-side duct 3091. The front cover portion 31 includes a second intake port 309.

The first cooling fan (first fan) 80 takes in air passing through the first intake port 308 and the first intake-port-side duct 3081 and discharges the air toward the first air outlet 3341. The second cooling fan (second fan) 90 takes in air passing through the second intake port 309 and the second intake-port-side duct 3091 and discharges the air toward the second air outlet 3342.

Placing the first cooling fan 80 at the center in the left-right direction of the cooling apparatus 3 (3b) enables the left-right position to be aligned with the air vent 247 provided at the bottom center of the image pickup apparatus 2. Thereby, the airflow path from the first cooling fan 80 to the air outlet 334 can be formed without bending it in the left-right direction, thereby suppressing a decrease in airflow due to flow-path losses.

The second cooling fan 90 is disposed so that a first cooling-fan intake port 801 and a second cooling-fan intake port 901 face opposite directions in the front-rear direction. Thereby, the second intake port 309 can be disposed on the front cover portion 31 and size reduction of the cooling apparatus 3 (3b) in the left-right direction can be achieved.

An air-outlet sealing member 3351 is provided around the first air outlet 3341 and the second air outlet 3342. Around the first air outlet 3341, the air-outlet sealing member 3351 is formed over the entire circumference to prevent air leakage between the air outlet and the air vent 247 of the image pickup apparatus 2. On the other hand, the air-outlet sealing member 3351 around the second air outlet 3342 is open on the front side of the image pickup apparatus 2. The opening of the air-outlet sealing member 3351 exhausts air discharged from the second air outlet 3342.

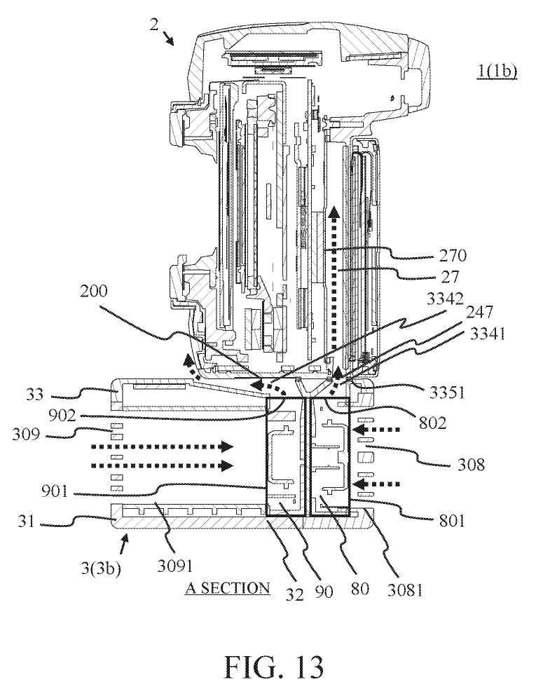

Next, with reference to FIG. 13, the internal structure of the imaging system 1 (1b) will be described. FIG. 13 is a sectional view taken along a line A-A in FIG. 1A in a direction orthogonal to the left-right direction of the imaging system 1 (1b).

When the first cooling fan 80 rotates, outside air is taken in from the first intake port 308, through the first intake-port-side duct 3081, and into the first cooling-fan intake port 801 of the first cooling fan 80. The first cooling fan 80 then discharges the taken-in air from a first cooling-fan exhaust port 802 by the rotation of its blades. The first air outlet 3341 discharges the air discharged from the first cooling-fan exhaust port 802. The camera duct 27 takes in the air discharged from the first air outlet 3341 through the air vent 247 of the image pickup apparatus 2 and discharges it from the exhaust port 261 of the image pickup apparatus 2.

When the second cooling fan 90 rotates, outside air is taken in from the second intake port 309, through the second intake-port-side duct 3091, and into the second cooling-fan intake port 901 of the second cooling fan 90. The second cooling fan 90 then discharges the taken-in air from a second cooling-fan exhaust port 902 by the rotation of its blades. The second air outlet 3342 discharges the air discharged from the second cooling-fan exhaust port 902. The second air outlet 3342 is opened so that its front side becomes larger than the bottom cover portion 200 of the image pickup apparatus 2. That is, the first air outlet 3341 is configured so that the entire opening is covered by the image pickup apparatus 2, whereas the second air outlet 3342 is configured so that a part of the opening is exposed from the image pickup apparatus 2.

With this structure, the second air outlet 3342 discharges the air discharged from the second air outlet 3342 after allowing the air to travel along the inner wall of the cooling apparatus 3 and the bottom cover portion 200 of the image pickup apparatus 2, and then discharging the air from the front-side opening formed by the image pickup apparatus 2 and the cooling apparatus 3 (3b). That is, the front-side opening of the air-outlet sealing member 3351 described above serves as an air discharge port.

At this time, the bottom cover portion 200 of the image pickup apparatus 2 is cooled by coming into contact with the air discharged from the second cooling-fan exhaust port 902 (the bottom cover portion 200 has a surface that comes into contact with the air), thereby dissipating heat from the bottom cover portion 200. The heat-dissipating metal plate 270 is cooled by coming into contact with the air passing through the camera duct 27, and dissipates heat from the ICs 227 and 228 via the heat transfer member 280.

Thereby, both the interior and the exterior member (exterior surface) of the image pickup apparatus 2 can be cooled, and even in harsh imaging environments such as high-temperature environments or under the flaming sun, the available imaging time is not reduced, and the driving time of the image pickup apparatus 2 can be extended compared with the image pickup apparatus 2 alone.

Independent fan control can be achieved by separately providing the first cooling fan 80 that cools the interior of the image pickup apparatus 2 and the second cooling fan 90 that cools the exterior member of the image pickup apparatus 2. For example, in an environment where the outside temperature is low, such as in winter, only the first cooling fan 80 may be rotated; or, just after recording starts, only the first cooling fan 80 may be rotated, and when the exterior surface temperature of the image pickup apparatus 2 reaches a desired temperature during recording, the second cooling fan 90 may also be rotated. Thereby, the operating noise generated during rotation of the first cooling fan 80 and the second cooling fan 90 can be reduced, while long-time operation with reduced power consumption can be achieved.

In this embodiment, each of the first cooling fan 80 and the second cooling fan 90 is a centrifugal fan. That is, air is taken in from the first cooling-fan intake port 801 and the second cooling-fan intake port 901 provided in the rotation axis direction of the blades, and discharged from the first cooling-fan exhaust port 802 and the second cooling-fan exhaust port 902 provided in the rotation diameter direction of the blades. At this time, the first cooling-fan exhaust port 802 and the second cooling-fan exhaust port 902 may be arranged so as to face the attachment direction (upper side in FIG. 13) of the cooling apparatus 3 (3b). Thereby, the housing size can be reduced in the optical-axis direction.

However, the present embodiment is not limited to this example, and each of the first cooling fan 80 and the second cooling fan 90 may be an axial fan that performs both intake and exhaust in the rotation axis direction of the blades. In this case, the first cooling fan 80 and the second cooling fan 90 may be arranged so as to overlap each other in the projection plane in the attachment direction of the cooling apparatus 3 (3b). Thereby, the housing size can be reduced in the optical-axis direction.

Alternatively, a combination of a centrifugal fan and an axial fan may be used for the first cooling fan 80 and the second cooling fan 90. That is, one of the first cooling fan 80 and the second cooling fan 90 may be a centrifugal fan, while the other may be an axial fan. In this embodiment, the first cooling fan 80 and the second cooling fan 90 are arranged such that the rotational axes of the blades align with the optical axis direction so as to discharge the taken-in air along the optical axis direction. However, the fans may instead be disposed in an up-down direction (vertical direction) perpendicular to the optical-axis direction or in an oblique direction.

Each embodiment can provide a cooling apparatus that can effectively cool the exterior surface of the image pickup apparatus.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-037095, filed on March 10, 2025, and which is hereby incorporated by reference herein in its entirety.

What is claimed is:

1. A cooling apparatus configured to cool an image pickup apparatus, the cooling apparatus comprising:
a fan unit configured to blow air; and
an exhaust unit configured to blow the air from the fan unit against an exterior surface of the image pickup apparatus.

2. The cooling apparatus according to claim 1, wherein the exhaust unit blows the air against the exterior surface of the image pickup apparatus and then sends the air into an interior of the image pickup apparatus.

3. The cooling apparatus according to claim 1, wherein the exhaust unit includes a first exhaust port for sending the air into an interior of the image pickup apparatus and a second exhaust port for blowing the air against the exterior surface of the image pickup apparatus.

4. The cooling apparatus according to claim 3, wherein the first exhaust port is configured so that an opening is entirely covered by the image pickup apparatus, and
wherein the second exhaust port is configured so that a part of the opening is exposed from the image pickup apparatus.

5. The cooling apparatus according to claim 3, further comprising a branching portion that branches the air from the fan unit into air directed toward the first exhaust port and air directed toward the second exhaust port.

6. The cooling apparatus according to claim 3, wherein the fan unit includes a plurality of fans,
wherein the exhaust section includes a plurality of exhaust ports, and
wherein the number of the plurality of fans is less than the number of the plurality of exhaust ports.

7. The cooling apparatus according to claim 3, wherein the fan unit includes a first fan that blows the air to a first exhaust port and a second fan that blows the air to a second exhaust port.

8. The cooling apparatus according to claim 7, wherein an intake port of the first fan and an intake port of the second fan are arranged facing opposite each other.

9. The cooling apparatus according to claim 1, wherein the fan unit is an axial fan unit.

10. The cooling apparatus according to claim 1, wherein the fan unit is a centrifugal fan unit.

11. The cooling apparatus according to claim 1, wherein the cooling apparatus is attachable to and detachable from the image pickup apparatus.

12. The cooling apparatus according to claim 11, wherein the exterior surface of the image pickup apparatus is a surface that contacts the cooling apparatus.

13. The cooling apparatus according to claim 11, wherein the exterior surface of the image pickup apparatus is a bottom surface of the image pickup apparatus.

14. The cooling apparatus according to claim 11, further comprising an attachment member for attaching the cooling apparatus to a tripod screw of the image pickup apparatus.
